(19) United States
(12) Patent Application Publication
(10) Pub. No.: US 2012/0267989 A1
(43) Pub. Date: Oct. 25, 2012

(54) DEVICE HOUSING AND METHOD FOR MAKING SAME

(75) Inventors: XIN-WU GUAN, Shenzhen City (CN); TIAN-FENG HUANG, Shenzhen City (CN); CHAO-SHENG HUANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/274,576

(22) Filed: Oct. 17, 2011

(30) Foreign Application Priority Data
Apr. 22, 2011 (CN) 201110101773.5

(51) Int. Cl. H05K 5/02; B32B 38/10; B32B 38/00; B32B 37/12

(52) U.S. Cl. 312/204; 156/60; 156/154; 156/150; 156/272.8; 156/250

(57) ABSTRACT

A device housing for an electronic device is provided. The device housing includes a metal main body and at least one metal decorative member. The metal main body has at least one receiving recess defined in an outer surface thereof. The at least one metal decorative member has a top surface. The top surface has a mirror finish. The at least one metal decorative member is received in the at least one receiving recess, with the top surface exposed out of the outer surface. The at least one metal decorative member forms a desired symbol, logo, or pattern on the device housing.

### BACKGROUND

1. Technical field

The present disclosure relates to device housings for electronic devices and a method for making the device housings.

2. Description of related art

Shells for portable electronic devices are usually decorated with symbols, logos, or patterns to attract consumers. A typical method for making these decorations on an aluminum shell includes the following steps: forming a concave pattern on a surface of a punching mold; punching an aluminum substrate using the punching mold to form a protruding pattern on the aluminum substrate; anodizing the surface to form an anodized oxide layer; mechanically removing portions of the anodized oxide layer covering the protruding pattern, causing portions of the aluminum substrate not covered by the anodized oxide layer and accordingly forming a predetermined symbol or logo. However, the symbol or logo protruding from the surface of the aluminum substrate may be easily abraded. Furthermore, it is hard to obtain a sufficient bright symbol or logo.

Therefore, there is room for improvement within the art.

### BRIEF DESCRIPTION OF THE DRAWINGS

Many aspects of the present device housing and method for making the same can be better understood with reference to the drawings. The components in the drawing are not necessarily drawn to scale, the emphasis instead being placed upon clearly illustrating the principles of the present device housing and method for making the same.

FIG. 1 is a partial exploded view of the present device housing according to an exemplary embodiment.

FIG. 2 is a partial assembled view of the present housing according to an exemplary embodiment.

FIG. 3 is a cross-section view of the device housing show in FIG. 2 taken along line III-III.

FIG. 4 is a cross-section view of the present housing according to a second exemplary embodiment.

### DETAILED DESCRIPTION

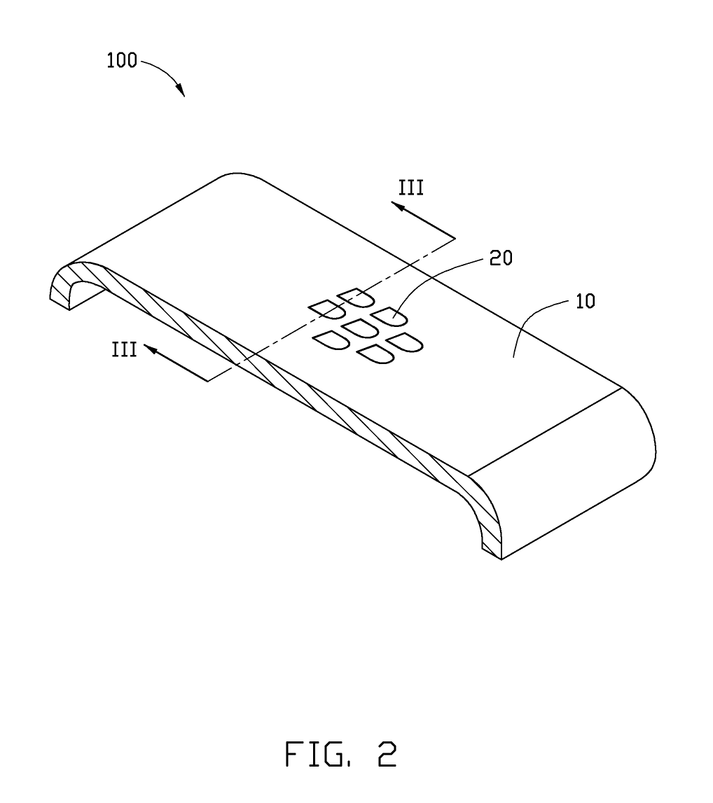

FIG. 2 shows an exemplary device housing 100 for electronic devices (such as mobile phones). In this exemplary embodiment, the device housing 100 is a cover of a mobile phone. The device housing 100 includes a main body 10 and at least one decorative member 20. In this exemplary embodiment, the device housing 100 includes a plurality of decorative members 20. The decorative members 20 are positioned within the main body 10 to form a desired symbol, logo, or pattern.

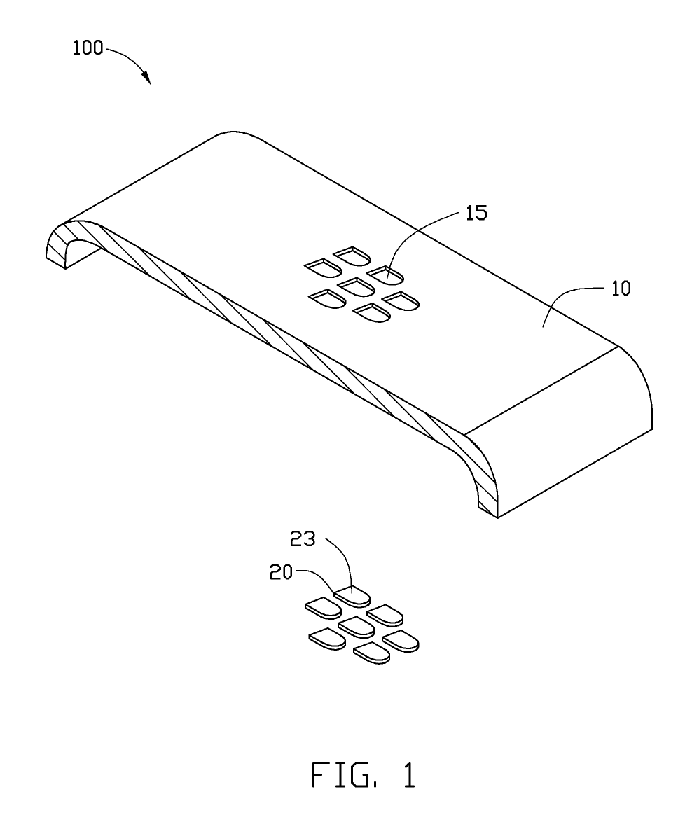

Referring to FIG. 1, the main body 10 includes an inner surface 12 and an opposite outer surface 14. The outer surface 14 has at least one receiving recess 15 defined. In this exemplary embodiment, the outer surface 14 defines a plurality of recesses 15. The receiving recesses 15 are designed to depict a desired symbol, logo, or pattern on the outer surface 14. The receiving recesses 15 cooperate to receive the decorative members 20. In this exemplary embodiment, each of the receiving recesses 15 has a depth of about 0.15 mm. The outer surface 14 may be defined by a colored anodized oxide layer 16 having a sandblasted pattern or a brushed texture of very fine lines, which may be resulted from a sandblasting process or a hairline finishing process followed by an anodizing process and a coloring process applied to the main body 10. The main body 10 may be made of a metal including examples such as aluminum, aluminum alloy, magnesium alloy, titanium, and titanium alloy, which can be anodized.

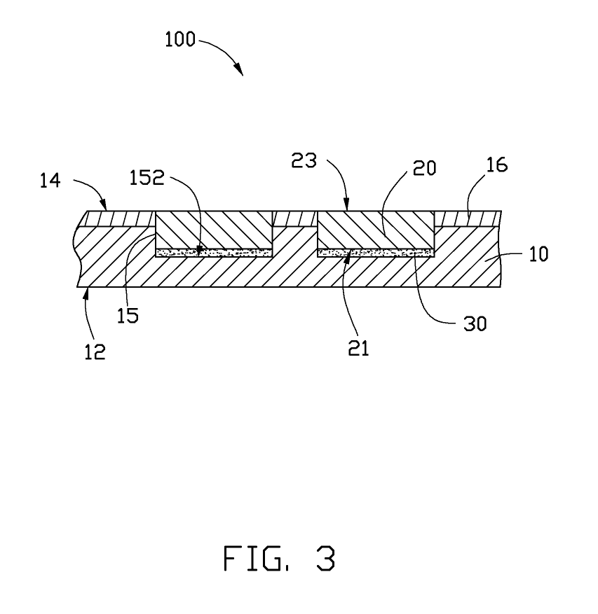

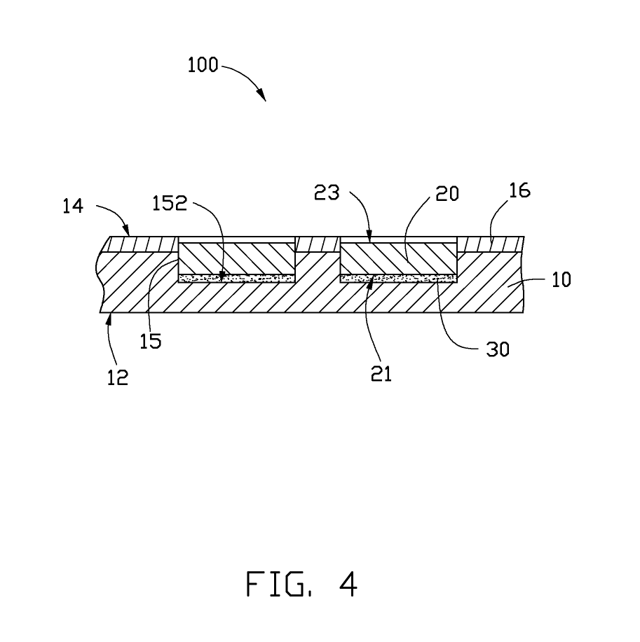

Referring to FIGS. 1 and 3, each decorative member 20 includes a bottom surface 21 and a top surface 23 opposite to the bottom surface 21. The top surface 23 may have a mirror finish and have a much higher gloss than the outer surface 14. Each decorative member 20 has a shape and size generally corresponding to the corresponding receiving recess 15, so the decorative members 20 can be received in the receiving recesses 15. The decorative members 20 are secured within the receiving recesses 15 by an adhesive layer 30, with the bottom surface 21 facing a bottom wall 152 of the receiving recesses 15 and the top surface 23 exposed out of the outer surface 14. The top surface 23 of the decorative members 20 may be coplanar with the outer surface 14. Alternatively, the top surface 23 may be lower than the outer surface 14 of the main body 10 (see FIG. 4). In this exemplary embodiment, each of the decorative members 20 has a thickness of about 0.1 mm and the top surface 23 of the decorative members 20 is substantially coplanar with the outer surface 14. The decorative members 20 are made of metal. In this exemplary embodiment, the decorative members 20 are made of stainless steel. The decorative members 20 can form a desired symbol, logo, or pattern on the device housing 100.

The adhesive layer 30 may be a heat-sensitive adhesive layer. The adhesive layer 30 is positioned between the decorative members 20 and the main body 10, securing the decorative members 20 within the corresponding receiving recesses 15.

An exemplary method for making the device housing 100 may include the following steps.

The main body 10 having the inner surface 12 and the outer surface 14 is provided. The main body 10 may be manufactured by stamping, for example.

The outer surface 14 is processed by sandblasting or hairline finishing, forming a sandblasted pattern or a brushed texture of very fine lines on the outer surface 14.

The outer surface 14 is then processed by anodizing and coloring, forming the colored anodized oxide layer 16 on the outer surface 14.

The receiving recesses 15 having the bottom wall 152 may be defined in the substrate 11 by laser engraving. In this exemplary embodiment, the laser engraving process may be carried out under the following parameters: a frequency of about 40 KHz, a power of about 20 W, an engraving rate of about 1 mm/s.

The decorative members 20 having the bottom surface 21 and the high glossy top surface 23 are provided. The decorative members 20 may be manufactured by laser cutting a stainless steel sheet which has a mirror surface having a high gloss. In another embodiment, the decorative members 20 may be manufactured by die-cutting.

The adhesive layer 30 is formed on the bottom surface 21 of the decorative members 20 such as by printing.

The decorative members 20 with the adhesive layer 30 are placed into the receiving recesses 15, with the adhesive layer 30 contacting the bottom wall 152 of the receiving recesses 15.

Then, the decorative members 20 are heat pressed at a temperature of about 65° C. to about 85° C., using a pressure of about 0.5 Mpa for about 3 seconds to 8 seconds. When cooled, the decorative members 20 are adhered in the receiving recesses 15 and form a desired symbol, logo, or pattern on the outer surface 14.

The top surface 23 of the decorative members 20 has a high gloss, while the outer surface 12 of the main body 10 is a sandblasted or hairline finished surface having a relative low gloss, allowing the symbol or logo formed by the decorative members 20 to have the desired contrast. Furthermore, the decorative members 20 are coplanar with the outer surface 12 and are not easily subjected to abrasions.

However, even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing, comprising:
a main body made of metal, the main body having an outer surface and an opposite inner surface, the outer surface having at least one receiving recess defined therein; and
at least one decorative member made of metal, the least one decorative member having a top surface and an opposite bottom surface, the top surface having a mirror finish, the at least one decorative member received in the at least one receiving recess, with the top surface exposed out of the outer surface.

2. The device housing as claimed in claim 1, wherein the outer surface is defined by a colored anodized oxide layer having a sandblasted pattern or a brushed texture of fine lines.

3. The device housing as claimed in claim 1, wherein the main body is selected from a group consisting of aluminum, aluminum alloy, magnesium alloy, titanium, and titanium alloy.

4. The device housing as claimed in claim 1, wherein the at least one decorative member is made of stainless steel.

5. The device housing as claimed in claim 1, wherein the at least one decorative member is secured within the at least one receiving recess by an adhesive layer located between the at least one decorative member and the main body.

6. The device housing as claimed in claim 1, wherein the adhesive layer is a heat-sensitive adhesive layer.

7. The device housing as claimed in claim 1, wherein the top surface of the at least one decorative member is coplanar with the outer surface of the main body.

8. The device housing as claimed in claim 1, wherein the top surface of the at least one decorative member is lower than the outer surface of the main body.

9. The device housing as claimed in claim 1, wherein the at least one decorative member forms a symbol, logo, or pattern on the device housing.

10. A method for making a device housing, comprising:
providing a main body made of metal, the main body having an outer surface and an opposite inner surface;
defining at least one receiving recess in the outer surface, the at least one receiving recess having a bottom wall;
providing at least one decorative member made of metal, the at least one decorative member having a top surface and an opposite bottom surface, the top surface having a mirror finish;
forming an adhesive layer on the bottom surface;
placing the at least one decorative member in the receiving recess, with the adhesive layer located between the at least one decorative member and the main body;
heat pressing the at least one decorative member.

11. The method as claimed in claim 10, further comprising a step of sandblasting or hairline finishing the outer surface, before the step of defining the at least one receiving recess.

12. The method as claimed in claim 11, further comprising a step of anodizing and coloring the outer surface, between the step of sandblasting or hairline finishing the outer surface and the step of defining the at least one receiving recess.

13. The method as claimed in claim 10, wherein the heat pressing is carried out at a temperature of about 65° C.-85° C., using a pressure of about 0.5 Mpa for about 3 seconds to 8 seconds.

14. The method as claimed in claim 10, wherein the at least one receiving recess is formed by laser engraving.

15. The method as claimed in claim 10, wherein the at least one decorative member is manufactured by laser cutting a stainless steel sheet having a mirror surface.

16. The method as claimed in claim 10, wherein the at least one decorative member is manufactured by die cutting.
